(19) United States
(12) Patent Application Publication
(10) Pub. No.: US 2024/0198346 A1
(43) Pub. Date: Jun. 20, 2024

(54) NANOSTRUCTURED SYSTEM FOR PHOTOTHERMAL HEATING AND METHODS OF MANUFACTURING THE SAME

(71) Applicant: Samsung Electronics Co., Ltd., Suwon-si (KR)

(72) Inventors: Vinayak Narasimhan, Altadena, CA (US); Radwanul Hasan Siddique, Monrovia, CA (US); Wonjong Jung, Seoul (KR); Kak Namkoong, Seoul (KR)

(21) Appl. No.: 18/157,041

(22) Filed: Jan. 19, 2023

Related U.S. Application Data
(60) Provisional application No. 63/433,714, filed on Dec. 19, 2022.

(51) Int. Cl. B01L 7/00; B01L 3/00; B81B 1/00; B81C 1/00

(52) U.S. Cl. CPC B01L 7/52; B01L 3/502707; B81B 1/00; B81C 1/00111; B01L 2300/168; B01L 2300/1805; B01L 2300/1894; B81B 2201/051; B81C 2201/0132

(57) ABSTRACT

A photothermal nanostructure device for photothermal heating includes a substrate having a first thermal conductivity, a light absorbing layer on a first side of the substrate and configured to absorb light in a wavelength range and to heat the substrate, and a thermally-insulative layer on the light absorbing layer and configured to reduce heat dissipation from the substrate, the thermally-insulative layer having a second thermal conductivity less than the first thermal conductivity.

### CROSS-REFERENCE TO RELATED APPLICATION(S)

This application claims priority to, and the benefit of, U.S. Provisional Application No. 63/433,714 (“NANOSTRUCTURED SYSTEM FOR PHOTOTHERMAL HEATING AND COOLING OF SEMICONDUCTOR CHIPS”), filed on Dec. 19, 2022, the entire content of which is incorporated herein by reference.

### FIELD

Aspects of the invention relate to the field of photothermal heating.

### BACKGROUND

Polymerase chain reaction (PCR) is considered the industry gold-standard nucleic acid (NA) amplification method. Amplification occurs by creating copies of the target nucleic acid cyclically. The amplification process involves cyclical thermocycling heating of the solution in which the NA is present and careful monitoring of the solution temperature.

Typical NA amplification tests take about one hour to perform. The test duration is often limited by the large reaction volumes and slow average heat ramp rates of traditional PCR reaction containers due to their poor thermal conductivity. While plastics such as polypropylene are most commonly used as containers to perform PCR, silicon can also be highly useful for this application. Silicon-based PCR chips are an improvement over their plastic counterparts due to a number of factors: 1) silicon is a good thermal conductor and can be thermocycled much more rapidly than plastics, which are poor thermal conductors, 2) silicon PCR chips are CMOS-compatible and can be integrated with complex logic for upstream and downstream processing, and 3) microfluidic circuits can be defined onto silicon PCR chips to greatly minimize reaction volumes saving costs and reducing thermocycling time. However, due to silicon's good thermal conductivity, its ability to dissipate heat is also high, which makes silicon a poor medium for trapping heat. Furthermore, due to silicon's high reflectivity (e.g., 30% to 40%) in visible and infrared wavelength ranges, optical thermocycling is challenging and inefficient.

The above information disclosed in this Background section is only for enhancement of understanding of the background of the invention, and therefore it may contain information that does not form the prior art.

### SUMMARY

Aspects of embodiments of the present invention are directed toward a multi-layer photothermal nanostructure device utilizing nanostructure integration into bulk silicon to enable rapid PCR thermocycling. The silicon-integrated nanostructure absorbs nearly all light in the ultraviolet-visible-near infrared wavelength ranges (e.g., about 250 nm to about 1000 nm) thereby substantially reducing the native reflection of plain silicon. The photothermal nanostructure device may include an optically transparent polymer thin-film with lower thermal conductance, as compared to silicon, over the nanostructures to not only mechanically protect the underlying nanostructures but to also slow down heat dissipation from the silicon chip. The thermal device may further include an anti-reflective film to minimize reflection losses from the introduction of the polymer film. Accordingly, the photothermal nanostructure device is able to achieve rapid thermal cycling of the assay solution, thus reducing the time required to perform NA amplification.

According to some exemplary embodiments of the present invention, there is provided a photothermal nanostructure device for photothermal heating, the photothermal nanostructure device including: a substrate having a first thermal conductivity; a light absorbing layer on a first side of the substrate and configured to absorb light in a wavelength range and to heat the substrate; and a thermally-insulative layer on the light absorbing layer and configured to reduce heat dissipation from the substrate, the thermally-insulative layer having a second thermal conductivity less than the first thermal conductivity.

In some embodiments, the substrate and the light absorbing layer include the same material and form a unitary and monolithic structure.

In some embodiments, the light absorbing layer includes a plurality of nanostructures etched out of a same silicon bulk forming the substrate, and the nanostructures are non-uniform in size and shape, and are configured to reduce native reflection of a bulk material forming the substrate.

In some embodiments, the light absorbing layer is configured to absorb more than 99% of incoming light in an ultraviolet to near infrared wavelength range.

In some embodiments, the thermally-insulative layer is configured to be optically transparent in an ultraviolet to near infrared wavelength range.

In some embodiments, the thermally-insulative layer includes at least one of polycarbonate (PC), poly(methyl methacrylate) (PMMA), acrylic, polyethylene terephthalate (PET), polyvinyl chloride (PVC), silicone rubber, cyclic olefin copolymers (COC), polyethylene (PE), ionomer resins, polypropylene (PP), polystyrene (PS), acrylonitrile butadiene styrene (ABS), polydimethylsiloxane (PDMS), or SU-8.

In some embodiments, the photothermal nanostructure device further includes: an anti-reflection layer on the thermally-insulative layer and configured to reduce reflection loss at an interface of the thermally-insulative layer and the anti-reflection layer.

In some embodiments, the anti-reflection layer includes at least one of a metal oxide, a metal nitride, a semiconductor oxide, or a semiconductor nitride.

In some embodiments, the substrate has a thickness of about 400 μm to about 1000 μm, the light absorbing layer has a thickness of about 100 nm to about 1 μm, the thermally-insulative layer has a thickness of about 10 μm to about 500 μm, the anti-reflection layer has a thickness of about 10 nm to about 500 nm, and the second thermal conductivity is at least 100 times smaller than the first thermal conductivity.

In some embodiments, the photothermal nanostructure device further includes: a fluidic circuit integrated within the substrate or at a second side of the substrate opposite from the first side, and being configured to contain a sample with a plurality of target molecules, wherein the substrate is configured to exchange heat with the sample.

According to some exemplary embodiments of the present invention, there is provided a photothermal diagnostics system including: a photothermal nanostructure device including: a substrate having a first thermal conductivity; a light absorbing layer on a backside of the substrate and configured to absorb light in a wavelength range and to heat the substrate; and a thermally-insulative layer on the light absorbing layer and configured to reduce heat dissipation from the substrate, the thermally-insulative layer having a second thermal conductivity less than the first thermal conductivity; a light source configured to heat the light absorbing layer by shining a light toward a backside of the photothermal nanostructure device; and a controller configured to control activation and deactivation of the light source.

In some embodiments, the light absorbing layer includes a plurality of nanostructures etched out of a same silicon bulk forming the substrate, and wherein the nanostructures are non-uniform in size and shape, and are configured to reduce native reflection of a bulk material forming the substrate.

In some embodiments, the substrate includes a fluidic circuit integrated within the substrate or at a topside of the substrate opposite from the backside, the fluidic circuit being configured to contain a sample with a plurality of target molecules, and the light source is configured to heat the sample via the light absorbing layer.

In some embodiments, the photothermal nanostructure device further includes: an anti-reflection layer on the thermally-insulative layer and configured to reduce reflection loss at an interface of the thermally-insulative layer and the anti-reflection layer.

In some embodiments, the photothermal diagnostics system further includes: a cooling device configured to cool a topside of the substrate opposite from the backside, wherein the controller is further configured to control operations of the cooling device, and to perform thermocycling on a sample within a fluidic circuit integrated within the substrate or at the topside of the substrate.

According to some exemplary embodiments of the present invention, there is provided a method of fabricating a nanostructure device for photothermal heating, the method including: providing a substrate; forming a light absorbing layer on a first side of the substrate, the light absorbing layer being configured to absorb light in a wavelength range and to heat the substrate; and forming a thermally-insulative layer on the light absorbing layer, the thermally-insulative layer being configured to reduce heat dissipation from the substrate.

In some embodiments, the forming the light absorbing layer includes etching the substrate via room-temperature or cryogenic reactive etching to generate nanostructure that are non-uniform in size and shape, and are configured to reduce native reflection of a bulk material forming the substrate.

In some embodiments, the forming the thermally-insulative layer includes coating a polymer on the light absorbing layer via at least one of spin coating, dip coating, spray coating, or drop casting.

In some embodiments, the method further includes: forming an anti-reflection layer on the thermally-insulative layer, the anti-reflection layer being configured to reduce reflection loss at an interface of the thermally-insulative layer and the anti-reflection layer.

In some embodiments, the forming the anti-reflection layer includes coating anti-reflective material on the thermally-insulative layer via at least one of vapor deposition, evaporation, or sputtering.

### BRIEF DESCRIPTION OF THE DRAWINGS

The above and other features and aspects of the invention will be made more apparent by the following detailed description of exemplary embodiments thereof with reference to the attached drawings, in which:

FIG. 1 illustrates a photothermal diagnostics system, according to some embodiments of the present invention.

FIGS. 2A-2B illustrate a top view and a bottom view, respectively, of a multi-layer photothermal nanostructure device, according to some embodiments of the present invention.

FIG. 2C illustrates a zoomed-in view of the region AA of FIG. 2B, according to some embodiments of the present invention.

FIG. 2D illustrates a zoomed-in view of the region BB of FIG. 2C, according to some embodiments of the present invention.

FIG. 3A is a graph illustrating the effect of a light absorption layer in improving the rate at which sample temperature may be increased, according to some embodiments of the present disclosure.

FIG. 3B is a graph illustrating the effect of a thermally-insulative layer in trapping heat and further improving the rate at which sample temperature may be increased, according to some embodiments of the present disclosure.

FIG. 4 illustrates a process of fabricating a multi-layer photothermal nanostructure device, according to some embodiments of the present invention.

### DETAILED DESCRIPTION

The attached drawings for illustrating exemplary embodiments of the invention are referred to in order to provide a sufficient understanding of the invention, the merits thereof, and the objectives accomplished by the implementation of the invention. The invention may, however, be embodied in many different forms and should not be construed as being limited to the exemplary embodiments set forth herein; rather, these exemplary embodiments are provided so that this invention will be thorough and complete, and will fully convey the concept of the invention to those skilled in the art.

Hereinafter, the invention will be described in detail by explaining exemplary embodiments of the invention with reference to the attached drawings. In the drawings, like reference numerals are used throughout the figures to reference like features and components.

Aspects of embodiments of the present invention are directed to a nanostructured and thin-film stack that may be utilized as photothermal heating layers for silicon-based PCR chips.

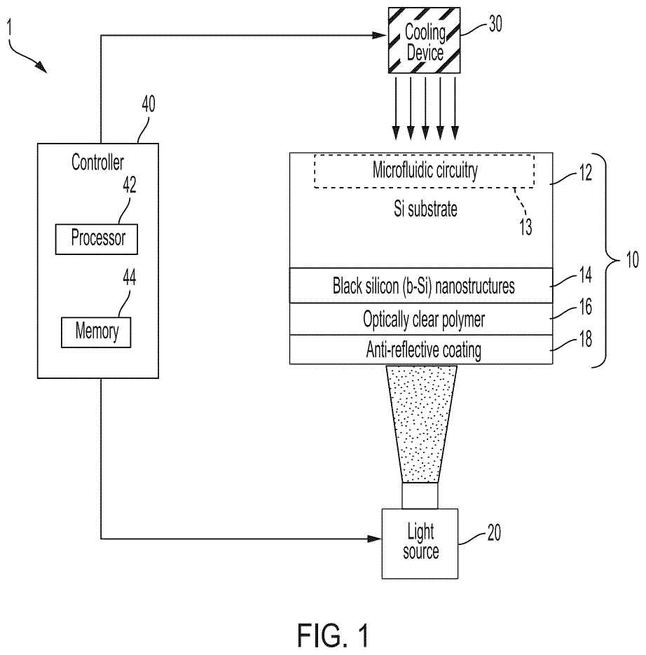

FIG. 1 illustrates a photothermal diagnostics system 1, according to some embodiments of the present invention.

According to some embodiments, the photothermal diagnostics system 1 includes a multi-layer photothermal nanostructure device 10, a light source 20, a cooling device 30, and a controller 40. The photothermal nanostructure device 10 includes a substrate 12, a light absorbing layer 14, and a thermally-insulative layer 16. In some embodiments, the photothermal nanostructure device 10 also include an anti-reflection layer 18. A fluidic circuitry (e.g., a microfluidic chip or microfluidic circuitry) 13 that is configured to contain a sample (e.g., a fluid) with a plurality of target molecules may be positioned on a top surface of the substrate 12 or the fluidic circuitry 13 may be integrated with and at least partially embedded in the substrate 12. The fluidic circuitry 13 may perform overall sample handling (i.e., accepting a sample and moving it from location to location, etc.) and may act as a reagent storage for those chemicals that are required to run a reaction on an inputted sample). The fluidic circuit 13 may also perform lysis, extraction, and amplification.

In some examples, the target molecules may be deoxyribonucleic acid (DNA) strands and the photothermal nanostructure device 10 may facilitate rapid polymerase chain reaction (PCR), which may amplify/multiply/copy segments of DNA. The PCR amplification and other nucleic acid amplification processes involve repeatedly cycling the temperature of the sample, which in the related art is a time-consuming process. The photothermal nanostructure device 10 is capable of significantly increasing the rate at which the sample temperature can be raised, thus shortening the duration of each thermal cycle and substantially increasing at which PCR amplification may be performed. For example, by utilizing the photothermal nanostructure device, thermal cycling time may be reduced from about 45 mins (as may be the case in the related art) to about 10 mins or less.

The controller 40 may enable the thermocycling of the sample within the fluidic circuitry 13 by controlling the operations (e.g., activating/turning on and deactivating/turning off) of the light source 20 and the cooling device 30. The controller 40 may include a processor 42 and a memory 44 local to the processor 42, which has instructions stored thereon that, when executed by the processor 42, cause the processor 42 to perform the processing operations of the controller 40.

The light source 20, which may include one or more light emitting diodes (e.g., LEDs), may heat the nanostructure device 10, and thus the sample, by shining light of a particular wavelength range (e.g., 250 nm to about 1000 nm) toward the backside of the nanostructure device 10. The cooling device 30, such as a cooling fan, a thermoelectric cooler (TEC), or a liquid cooling module, may cool the sample within the fluidic circuitry 13 by cooling the topside of the nanostructure device 10. In addition to performing thermocycling, the controller 40 may monitor the PCR amplification process.

In some embodiments, the light absorbing layer 14 is on a first side (e.g., the backside) of the substrate 12 and is configured to absorb light in a particular wavelength range (e.g., 250 nm to 1000 nm) and to convert the energy of the absorbed light into heat energy, which is transferred to the substrate 12. The light absorbing layer 14 includes a plurality of nanostructures that are etched out of a same bulk material (e.g., silicon bulk) forming the substrate 12. As such, the substrate 12 and the light absorbing layer 14 may form a unitary and monolithic structure. In some examples, the nanostructures may be non-uniform in size and shape, which may allow the light absorbing layer 14 to absorb a broadband spectrum of light wavelengths. For example, the light absorbing layer 14 may absorb about 99% or more of incoming light in the ultraviolet to near infrared wavelengths (e.g., 250 nm to about 1000 nm). Thus, the light absorbing layer 14 may substantially reduce the native reflection of the substrate 12, which may be bulk silicon. The substrate 12 (e.g., a silicon substrate) may exhibit high thermal conductivity. Therefore, the heat generated by the light absorbing layer 14 may be readily transferred to the fluidic circuit 13 through the substrate 12.

According to some embodiments, the thermally-insulative layer 16 covers a side of the light absorbing layer 14 that is opposite from the substrate 12 and is configured to restrict (e.g., substantially prevent) the dissipation of heat from the light absorbing layer 14 in a direction away from the substrate 12. To achieve this heat trapping effect, the thermally-insulative layer may have a thermal conductivity that is substantially less (e.g., about 100 times less) than that of the first thermal conductivity. As the surface area of the top and bottom surfaces of the light absorbing layer 14 far exceed the area of the layer's side surfaces, most of the heat dissipation at the light absorbing layer 14 occurs at the top and bottom surfaces of the light absorbing layer 14. By limiting heat transfer through the bottom surface of the light absorbing layer 14, the thermally-insulative layer 16 ensures that majority of (e.g., nearly all of) the heat transfer from the light absorbing layer 14 is directed towards the substrate 12. This further improves the rate at which the sample may be heated.

The material of the thermally-insulative layer 16 may be chosen to be optically transparent in the wavelength range of the light source 20 so as not to block the light from the light source 20 from reaching the light absorbing layer 14. For example, the thermally-insulative layer 16 may be optically transparent in the ultraviolet to near infrared wavelength range. In some examples, the thermally-insulative layer may include polycarbonate (PC), poly(methyl methacrylate) (PMMA), acrylic, polyethylene terephthalate (PET), polyvinyl chloride (PVC), silicone rubber, cyclic olefin copolymers (COC), polyethylene (PE), ionomer resins, polypropylene (PP), polystyrene (PS), acrylonitrile butadiene styrene (ABS), polydimethylsiloxane (PDMS), SU-8, and/or the like.

Despite being optically transparent in the desired wavelength range, the air-insulative layer interface may reflect some of the incident light (e.g., about 4% to 5% of the incident light) from the light source 20. To prevent this reflection and to ensure maximal light transmission to the light absorbing layer 14, the photothermal nanostructure device 10 may further include an anti-reflection layer 18 that coats the bottom surface of the thermally-insulative layer 16 and is configured to reduce reflection losses at the interface of the thermally-insulative layer 16 and the anti-reflection layer. For example, while a silicon substrate may have a reflectivity of about 40%, and the reflectivity of the combination of the substrate and light absorption layer may be less than 1%, after adding the thermally-insulative layer 16, the reflectivity of the stack may drop to about 5%. By coating this layer with the anti-reflection layer 18, the total reflectivity of the backside of the multi-layer photothermal nanostructure device 10 may once again be less than 1%. The anti-reflection layer 18 may include a metal oxide, a metal nitride, a semiconductor oxide, a semiconductor nitride, and/or the like. The thickness of the anti-reflection layer 18 may be determine based on the wavelength of the light emitted by the light source 20.

In some examples, the substrate 12 may have a thickness of about 400 μm to about 1000 μm, the light absorbing layer 14 may have a thickness of about 100 nm to about 1 μm, the thermally-insulative layer 16 may have a thickness of about 10 μm to about 500 μm, and the anti-reflection layer 18 may have a thickness of about 10 nm to about 500 nm.

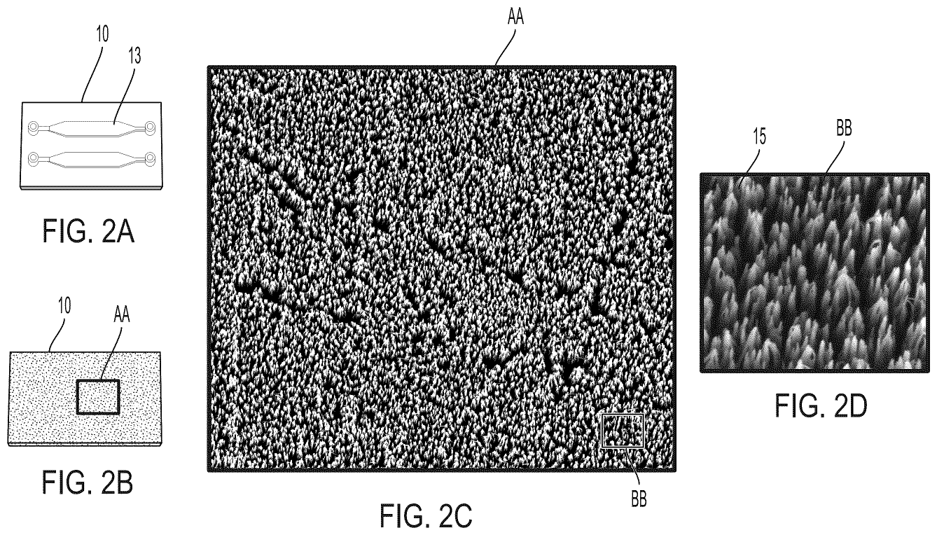

FIGS. 2A-2B illustrate a top view and a bottom view, respectively, of the multi-layer photothermal nanostructure device 10, according to some embodiments of the present invention. FIG. 2C illustrates a zoomed-in view of the region AA of FIG. 2B, according to some embodiments of the present invention. FIG. 2D illustrates a zoomed-in view of the region BB of FIG. 2C, according to some embodiments of the present invention.

As shown in FIGS. 2A-2B, the topside of the silicon substrate 12, which may be polished, is reflective, while the bottom side of the light absorption layer (e.g., a black silicon layer) 14 appears black as it absorbs nearly all light in the visible light range. As shown in FIGS. 2C and 2D, the light absorbing layer 14 includes a large number of densely packed etched features 15, which may have a tree-like structure. The etched features 15 may be nanoscale or micro-scale; however, nano-scale features may offer higher light absorption. The level of randomness in size and shape of the features 15 determines the range of light wavelengths that may be absorbed by the light absorbing layer 14. For example, the higher the level of randomness, the greater the range of the absorbed wavelengths. The material of the light absorbing layer 14 determines the thermal conductivity of the layer.

While in the above description, the features 15 are formed by etching material away from the bulk material of the substrate 12, embodiments of the present disclosure are not limited thereto. For example, the features 15 may be grown on the substrate 12.

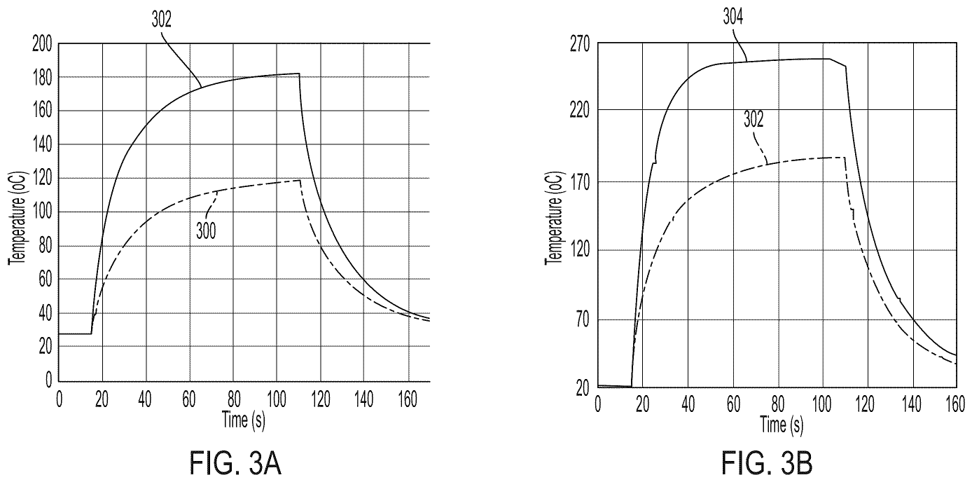

FIG. 3A is a graph illustrating the effect of the light absorbing layer 14 in improving the rate at which sample temperature may be increased, according to some embodiments of the present disclosure. FIG. 3B is a graph illustrating the effect of the thermally-insulative layer 16 in trapping heat and further improving the rate at which sample temperature may be increased, according to some embodiments of the present disclosure.

In the example of FIG. 3A, when performing photothermal heating of bulk silicon using light of 450 nm, one thermal cycle may follow the curve 300, which rises slowly to a maximum temperature of about 120° C. in about 100 seconds. The rate of temperature increase as well as the maximum temperature attained may be restrained due to silicon's inability to absorb all of the incident light and also due to the rapid dissipation of heat by silicon resulting from its high thermal conductivity.

When emitting the same light onto bulk silicon that has etched nanostructures 15 formed thereon (thus forming a light absorbing layer 14), the rate of temperature rise of the bulk silicon as well as the maximum temperature attained in the same period of time (e.g., about 100 seconds) significantly increases, as shown by curve 302. For example, the bulk silicon may reach about 187 ºC in about 100 seconds, with a heat ramp of 9° C./sec (as measured from about 55° C. to about 95° C.). This is due to the ability of black silicon to absorb nearly all the incident light and to convert the absorbed energy to thermal energy, which is partially transferred to the bulk silicon. The heat transfer performance of the light absorbing layer 14 may be further improved by utilizing a thermally-insulative layer 16 to cover the exposed backside of the light absorbing layer 14.

In the example of FIG. 3B in which a thermally-insulative layer 16 made of SU-8 is used to cover the black silicon making up the light absorbing layer 14, the rise in temperature follows curve 304. As shown, the heat trapping effect of the optically transparent SU-8 film greatly increases the rate at which the bulk silicon temperature rises and also increases the maximum temperature that can be attained in the same period of time. For example, the bulk silicon may reach about 258° C. in about 100 seconds, with a heat ramp of 23° C./sec (as measured from about 55° C. to about 95° C.). While not show in the graphs, this photothermal performance may be further improved by employing an the anti-reflection layer 18 to reduce reflections of the incident light from the light source 20.

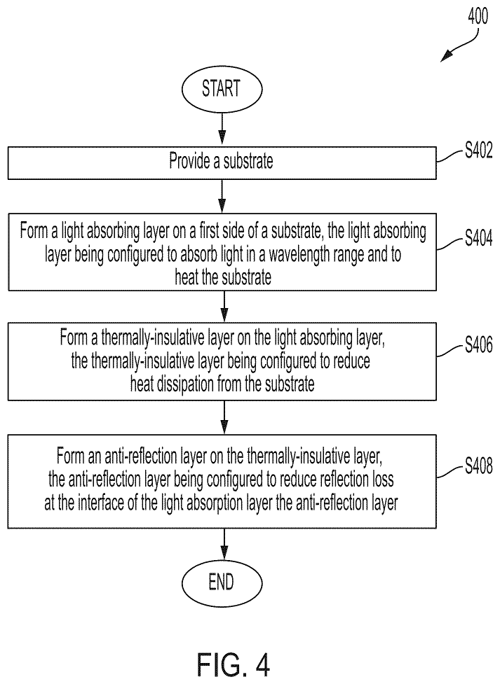

FIG. 4 illustrates a process 400 of fabricating a multi-layer photothermal nanostructure device 10, according to some embodiments of the present invention.

In some embodiments, the fabrication process includes providing a substrate 12 (S402), and forming a light absorbing layer 14 on a first side of a substrate 12 (S404). Forming the light absorbing layer may include etching the substrate via room-temperature or cryogenic reactive etching to generate nanostructure 15 that are non-uniform in size and shape and are configured to reduce native reflection of the bulk material forming the substrate. The light absorbing layer is configured to absorb light in a wavelength range and to heat the substrate 12.

In some embodiments, the fabrication process further includes forming a thermally-insulative layer 16 on the light absorbing layer 14 (S406), which can reduce heat dissipation from the substrate 12. Forming the thermally-insulative layer 16 may include coating a polymer on the light absorbing layer 14 via spin coating, dip coating, spray coating, drop casting, and/or the like. The polymer may be optically transparent in the ultraviolet to near infrared wavelength range.

The fabrication process may further include forming an anti-reflection layer 18 on the thermally-insulative layer 16 (S408). The anti-reflection layer 18 is configured to reduce reflection loss at the interface of the thermally-insulative layer 16 and the anti-reflection layer 18. Forming the anti-reflection layer may include coating anti-reflective material on the thermally-insulative layer 16 via vapor deposition, evaporation, sputtering and/or the like.

Accordingly, as described above, embodiments of the present invention provide a multi-layer photothermal nanostructure device that enables rapid thermal cycling. A nanostructured light absorption layer that is integrated into the bulk material forming the substrate of the device absorbs nearly all light in the ultraviolet-visible-near infrared wavelength ranges and converts the received energy to thermal energy for heating a sample contained in the photothermal nanostructure device. The device may further include an optically transparent thermally-insulative layer (such as a polymer thin-film) with lower thermal conductance relative to the substrate (which may be made of silicon), over the nanostructures to not only mechanically protect the underlying nanostructures but to also slow down heat dissipation from the fluidic circuitry housed in the device. The thermal device may further utilize an anti-reflective film to minimize reflection losses from the introduction of the thermally-insulative layer. Accordingly, the photothermal nanostructure device is able to achieve rapid thermal cycling of the assay solution, thus reducing the time required to perform NA amplification.

While this invention has been described in detail with particular references to illustrative embodiments thereof, the embodiments described herein are not intended to be exhaustive or to limit the scope of the invention to the exact forms disclosed. Persons skilled in the art and technology to which this invention pertains will appreciate that alterations and changes in the described structures and methods of assembly and operation can be practiced without meaningfully departing from the principles, spirit, and scope of this invention, as set forth in the following claims and equivalents thereof.

It will be understood that, although the terms “first,” “second,” “third,” etc., may be used herein to describe various elements, components, and/or sections, these elements, components, and/or sections should not be limited by these terms. These terms are used to distinguish one element, component, or section from another element, component, or section. Thus, a first element, component, or section discussed above could be termed a second element, component, or section, without departing from the spirit and scope of the invention.

It will be understood that the spatially relative terms used herein are intended to encompass different orientations of the device in use or in operation, in addition to the orientation depicted in the figures. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the invention. As used herein, the singular forms “a” and “an” are intended to include the plural forms as well, unless the context clearly indicates otherwise. It will be further understood that the terms “include,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Further, the use of “may” when describing embodiments of the invention refers to “one or more embodiments of the invention.” Also, the term “exemplary” is intended to refer to an example or illustration.

It will be understood that when an element or component is referred to as being “connected to” or “coupled to” another element or component, it can be directly connected to or coupled to the other element or component, or one or more intervening elements or components may be present. When an element or layer is referred to as being “directly connected to” or “directly coupled to” another element or component, there are no intervening elements or components present.

As used herein, the terms “substantially,” “about,” and similar terms are used as terms of approximation and not as terms of degree, and are intended to account for the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

For the purposes of this disclosure, “one or more of X, Y, and Z”, “at least one of X, Y, or Z” and “at least one selected from the group consisting of X, Y, and Z” may be construed as X only, Y only, Z only, or any combination of two or more of X, Y, and Z, such as, for instance, XYZ, XYY, YZ, and ZZ.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112, first paragraph, and 35 U.S.C. § 132(a).

The controller and/or any other relevant devices or components according to embodiments of the present invention described herein may be implemented by utilizing any suitable hardware, firmware (e.g., an application-specific integrated circuit), software, or a suitable combination of software, firmware, and hardware. For example, the various components of the controller may be formed on one integrated circuit (IC) chip or on separate IC chips. Further, the various components of the controller may be implemented on a flexible printed circuit film, a tape carrier package (TCP), a printed circuit board (PCB), or formed on the same substrate. Further, the various components of the controller may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer-readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the present invention.

While this invention has been described in detail with particular references to illustrative embodiments thereof, the embodiments described herein are not intended to be exhaustive or to limit the scope of the invention to the exact forms disclosed. Persons skilled in the art and technology to which this invention pertains will appreciate that suitable alterations and changes in the described structures and methods can be practiced without meaningfully departing from the principles, spirit, and scope of this invention, as set forth in the following claims and equivalents thereof.

What is claimed is:

1. A photothermal nanostructure device for photothermal heating, the photothermal nanostructure device comprising:
a substrate having a first thermal conductivity;
a light absorbing layer on a first side of the substrate and configured to absorb light in a wavelength range and to heat the substrate; and
a thermally-insulative layer on the light absorbing layer and configured to reduce heat dissipation from the substrate, the thermally-insulative layer having a second thermal conductivity less than the first thermal conductivity.

2. The photothermal nanostructure device of claim 1, wherein the substrate and the light absorbing layer comprise the same material and form a unitary and monolithic structure.

3. The photothermal nanostructure device of claim 1, wherein the light absorbing layer comprises a plurality of nanostructures etched out of a same silicon bulk forming the substrate, and
wherein the nanostructures are non-uniform in size and shape, and are configured to reduce native reflection of a bulk material forming the substrate.

4. The photothermal nanostructure device of claim 1, wherein the light absorbing layer is configured to absorb more than 99% of incoming light in an ultraviolet to near infrared wavelength range.

5. The photothermal nanostructure device of claim 1, wherein the thermally-insulative layer is configured to be optically transparent in an ultraviolet to near infrared wavelength range.

6. The photothermal nanostructure device of claim 1, wherein the thermally-insulative layer comprises at least one of polycarbonate (PC), poly(methyl methacrylate) (PMMA), acrylic, polyethylene terephthalate (PET), polyvinyl chloride (PVC), silicone rubber, cyclic olefin copolymers (COC), polyethylene (PE), ionomer resins, polypropylene (PP), polystyrene (PS), acrylonitrile butadiene styrene (ABS), polydimethylsiloxane (PDMS), or SU-8.

7. The photothermal nanostructure device of claim 1, further comprising:
an anti-reflection layer on the thermally-insulative layer and configured to reduce reflection loss at an interface of the thermally-insulative layer and the anti-reflection layer.

8. The photothermal nanostructure device of claim 7, wherein the anti-reflection layer comprises at least one of a metal oxide, a metal nitride, a semiconductor oxide, or a semiconductor nitride.

9. The photothermal nanostructure device of claim 7,
wherein the substrate has a thickness of about 400 μm to about 1000 μm,
wherein the light absorbing layer has a thickness of about 100 nm to about 1 μm,
wherein the thermally-insulative layer has a thickness of about 10 μm to about 500 μm,
wherein the anti-reflection layer has a thickness of about 10 nm to about 500 nm, and
wherein the second thermal conductivity is at least 100 times smaller than the first thermal conductivity.

10. The photothermal nanostructure device of claim 1, further comprising:
a fluidic circuit integrated within the substrate or at a second side of the substrate opposite from the first side, and being configured to contain a sample with a plurality of target molecules,
wherein the substrate is configured to exchange heat with the sample.

11. A photothermal diagnostics system comprising:
a photothermal nanostructure device comprising:
a substrate having a first thermal conductivity;
a light absorbing layer on a backside of the substrate and configured to absorb light in a wavelength range and to heat the substrate; and
a thermally-insulative layer on the light absorbing layer and configured to reduce heat dissipation from the substrate, the thermally-insulative layer having a second thermal conductivity less than the first thermal conductivity;
a light source configured to heat the light absorbing layer by shining a light toward a backside of the photothermal nanostructure device; and
a controller configured to control activation and deactivation of the light source.

12. The photothermal diagnostics system of claim 11, wherein the light absorbing layer comprises a plurality of nanostructures etched out of a same silicon bulk forming the substrate, and
wherein the nanostructures are non-uniform in size and shape, and are configured to reduce native reflection of a bulk material forming the substrate.

13. The photothermal diagnostics system of claim 11, wherein the substrate comprises a fluidic circuit integrated within the substrate or at a topside of the substrate opposite from the backside, the fluidic circuit being configured to contain a sample with a plurality of target molecules, and
wherein the light source is configured to heat the sample via the light absorbing layer.

14. The photothermal diagnostics system of claim 11, wherein the photothermal nanostructure device further comprises:
an anti-reflection layer on the thermally-insulative layer and configured to reduce reflection loss at an interface of the thermally-insulative layer and the anti-reflection layer.

15. The photothermal diagnostics system of claim 11, further comprising:
a cooling device configured to cool a topside of the substrate opposite from the backside,
wherein the controller is further configured to control operations of the cooling device, and to perform thermocycling on a sample within a fluidic circuit integrated within the substrate or at the topside of the substrate.

16. A method of fabricating a nanostructure device for photothermal heating, the method comprising:
providing a substrate;
forming a light absorbing layer on a first side of the substrate, the light absorbing layer being configured to absorb light in a wavelength range and to heat the substrate; and
forming a thermally-insulative layer on the light absorbing layer, the thermally-insulative layer being configured to reduce heat dissipation from the substrate.

17. The method of claim 16, wherein the forming the light absorbing layer comprises etching the substrate via room-temperature or cryogenic reactive etching to generate nanostructure that are non-uniform in size and shape, and are configured to reduce native reflection of a bulk material forming the substrate.

18. The method of claim 16, wherein the forming the thermally-insulative layer comprises coating a polymer on the light absorbing layer via at least one of spin coating, dip coating, spray coating, or drop casting.

19. The method of claim 16, further comprising:
forming an anti-reflection layer on the thermally-insulative layer, the anti-reflection layer being configured to reduce reflection loss at an interface of the thermally-insulative layer and the anti-reflection layer.

20. The method of claim 19, wherein the forming the anti-reflection layer comprises coating anti-reflective material on the thermally-insulative layer via at least one of vapor deposition, evaporation, or sputtering.
